(19) United States
(12) Patent Application Publication
(10) Pub. No.: US 2014/0210566 A1
(43) Pub. Date: Jul. 31, 2014

(54) CRYSTAL RESONATOR, CRYSTAL RESONATOR PACKAGE, AND CRYSTAL OSCILLATOR

(71) Applicant: NIHON DEMPA KOGYO CO., LTD., TOKYO (JP)

(72) Inventors: MITSUAKI KOYAMA, SAITAMA (JP); TAKERU MUTOH, SAITAMA (JP); NAOKI ONISHI, SAITAMA (JP)

(73) Assignee: NIHON DEMPA KOGYO CO., LTD., TOKYO (JP)

(21) Appl. No.: 14/156,415

(22) Filed: Jan. 15, 2014

(30) Foreign Application Priority Data
Jan. 29, 2013 (JP) 2013-013851
May 15, 2013 (JP) 2013-103390
Jul. 10, 2013 (JP) 2013-144519

(51) Int. Cl. H03B 5/30

(52) U.S. Cl. CPC H03B 5/30
USPC 331/158

(57) ABSTRACT

A crystal resonator includes a crystal element and excitation electrodes. The crystal element includes an α crystal region and a β crystal region that have mutually different positive/negative directions along an X-axis. Each two or more of the α crystal regions and the β crystal regions are alternately formed along a direction perpendicular to the X-axis. The excitation electrodes are formed on both surfaces of the respective α crystal region and β crystal region other than crystal regions positioned at both end portions of a row of the α crystal regions and the β crystal regions.

### CROSS-REFERENCE TO RELATED APPLICATION

This application claims the priority benefit of Japanese application serial no. 2013-013851, filed on Jan. 29, 2013, Japanese application serial no. 2013-103390, filed on May 15, 2013, and Japanese application serial no. 2013-144519, filed on Jul. 10, 2013. The entirety of each of the above-mentioned patent applications is hereby incorporated by reference herein and made a part of this specification.

### BACKGROUND

1. Technical Field

The present disclosure relates to a crystal resonator that includes vibrating regions with respective mutually different positive/negative directions along the X-axis, a crystal resonator package that includes the crystal resonator, and a crystal oscillator.

2. Description of the Related Art

A crystal resonator is widely used in industrial fields such as information, communication, and sensors. In particular, in the communication field, there are quite a few requests for frequency stability of ±1 ppm or less. To achieve these requests, for example, a temperature compensated crystal oscillator (TCXO) and an oven controlled crystal oscillator (OCXO) are widely used.

For example, the TCXO employs a thermistor as a temperature sensor. Temperature information detected by this thermistor is used as an electrical signal to control temperature characteristics of a crystal oscillator through a temperature control circuit, so as to ensure a predetermined frequency stability. However, there is time difference in temperature reaction between the crystal resonator and the thermistor. A consequent problem is that it is difficult to apply the crystal resonator to a product requiring severe frequency stability.

In response to this problem, for example, a proposed crystal resonator includes a plurality of vibrating regions formed in the same crystal element as described in Japanese Unexamined Patent Application Publication No. 2000-36723. The inventor has examined the following crystal oscillator. For example, a part of an AT-cut crystal element is heated so as to form a BT-cut region in which positive and negative are inverted with respect to the X-axis of the original crystal element. Assume that the region of the original crystal element without heating is referred to as an α crystal portion while the BT-cut region is referred to as a β crystal portion. In this case, a frequency-temperature property of the α crystal portion is expressed by a third-order curve while a frequency-temperature property of the β crystal portion is expressed by a first-order curve. Therefore, highly-accurate temperature compensation is expected by using an oscillation frequency (a fundamental wave) of the β crystal portion as a temperature detection signal to correct a signal corresponding to a frequency setting value of the α crystal portion based on this temperature detection signal.

Incidentally, in the case where the crystal resonator is used for oscillation, the symmetry of the elastic vibration may become a problem. In the case where a part of the AT-cut crystal element is heated to form the BT-cut region, as illustrated in FIG. 6, an boundary surface 5 between an AT-cut α crystal region 2 and a BT-cut β crystal region 3 is curved to penetrate into the α crystal region 2 side and is formed as an inclined surface. Accordingly, each of the a crystal region 2 and the β crystal region 3 does not have a symmetrical shape. In the case where a crystal element in an asymmetrical shape is vibrated, an asymmetric vibration occurs and the oscillation frequency is unstable. Thus, Activity dips may appear.

The present disclosure has been made in view of the aforementioned problems, and an aim thereof is to provide a technique that allows obtaining a stable oscillation output with a simple configuration in a crystal resonator that includes vibrating regions that have respective mutually different positive/negative directions along the X-axis.

### SUMMARY

A crystal resonator of the present disclosure includes a crystal element and excitation electrodes. The crystal element includes an α crystal region and a β crystal region. The a crystal region and the β crystal region have mutually different positive/negative directions along an X-axis. Each two or more of the α crystal regions and the β crystal regions are alternately formed along a direction perpendicular to the X-axis. The excitation electrodes are formed on both surfaces of the respective α crystal region and β crystal region other than crystal regions positioned at both end portions of a row of the α crystal regions and the β crystal regions.

The crystal element may have a rectangular shape. The crystal element may be formed in a rectangular shape with a long side that extends in an extending direction of the X-axis.

A row of the α crystal regions and the β crystal regions may intervene between the a crystal region where the excitation electrode is disposed and the β crystal region where the excitation electrode is disposed. Further, the crystal element may be cut out by AT cut. One region of the α crystal region and the β crystal region may be an AT-cut region that has a positive/negative direction along the X-axis. The positive/negative direction is the same as the positive/negative direction when the crystal element is cut out. Alternatively, a boundary surface between the α crystal region and the β crystal region may be a surface inclined at 25° to 45° with respect to a longitudinal direction when viewed from a direction of the X-axis.

A crystal resonator package of the present disclosure includes the above-described crystal resonator within a container and an electrode portion disposed at the container. The electrode portion electrically connects respective excitation electrodes and an external conductive path.

A crystal oscillator of the present disclosure includes the above-described crystal resonator, a first oscillator circuit, a second oscillator circuit, and a correction unit. The first oscillator circuit is connected to an excitation electrode disposed in the AT-cut region. The second oscillator circuit is connected to an excitation electrode disposed in a crystal region that has an opposite positive/negative direction along the X-axis with respect to the positive/negative direction of the AT-cut region. The correction unit is configured to: estimate a temperature of the crystal resonator based on an output frequency of the second oscillator circuit; and correct a setting signal corresponding to a setting value of an oscillation frequency of the first oscillator circuit based on the estimated temperature.

The crystal region that has the opposite positive/negative direction along the X-axis with respect to the positive/negative direction of the AT-cut region may include: a crystal region that has an opposite positive/negative direction along the X-axis with respect to the positive/negative direction of the first AT-cut region along the X-axis; and a crystal region that has an opposite positive/negative direction along the X-axis with respect to the positive/negative direction of the second AT-cut region along the X-axis. The excitation electrode connected to the second oscillator circuit may be disposed in the crystal region that has the opposite positive/negative direction along the X-axis with respect to the positive/negative direction of the first AT-cut region along the X-axis. The first waveform shaping crystal resonator may be connected to a capacitor for adjusting impedance in series. The capacitor for adjusting impedance may be constituted such that an electrode for excitation is disposed in the crystal region that has the opposite positive/negative direction along the X-axis with respect to the positive/negative direction of the second AT-cut region along the X-axis.

Further, in the crystal oscillator of the present disclosure, the AT-cut region may include a first AT-cut region and a second AT-cut region. The excitation electrode connected to the first oscillator circuit may be disposed in the first AT-cut region. One of an inside and an outside of an oscillation loop of the first oscillator circuit may be connected to a first waveform shaping crystal resonator. The first waveform shaping crystal resonator is configured to shape a frequency signal to a sine wave. The first waveform shaping crystal resonator may be constituted such that an electrode for excitation is disposed in the second AT-cut region. Accordingly, as the AT-cut region, a third AT-cut region may further be disposed. Another of the inside and the outside of the oscillation loop may be connected to a second waveform shaping crystal resonator. The second waveform shaping crystal resonator is configured to shape a frequency signal to a sine wave. The second waveform shaping crystal resonator may be constituted such that an electrode for excitation is disposed in the third AT-cut region.

The crystal resonator of the present disclosure includes the α crystal region and the β crystal region that have mutually different positive/negative directions along an X-axis in the crystal element. Each two or more of the α crystal regions and the β crystal regions are alternately formed along a direction perpendicular to the X-axis. The excitation electrodes are formed on both surfaces of the respective α crystal region and β crystal region other than crystal regions positioned at both end portions. Thus, vibrating regions are formed. Therefore, the a crystal region where a first vibrating region is disposed is sandwiched between the β crystal regions from both sides. The β crystal region to be a second vibrating region is also sandwiched between the α crystal regions from both sides. Accordingly, the respective regions have symmetrical shapes. In case of oscillation, the symmetry of the vibration becomes high. This reduces the occurrence of Activity dips.

### BRIEF DESCRIPTION OF THE DRAWINGS

FIG. 1A and FIG. 1B are perspective views respectively illustrating a front surface and a back surface of a crystal resonator according to an embodiment of the present disclosure.

FIG. 2 is a cross-sectional side view taken along the line I-I′ of the crystal resonator according to the embodiment of the present disclosure.

FIG. 3 is a plan view illustrating a crystal element used in the crystal resonator.

FIG. 4 is a transparent perspective view illustrating the crystal element used in the crystal resonator.

FIG. 5A and FIG. 5B are explanatory views illustrating a fabrication process of the crystal resonator according to the embodiment of the present disclosure.

FIG. 6 is a transparent perspective view illustrating a crystal element where twins are formed.

FIG. 7 is a plan view illustrating another example of the crystal resonator according to the embodiment of the present disclosure.

FIG. 8 is a plan view illustrating another example of the crystal resonator according to the embodiment of the present disclosure.

FIG. 9 is a cross-sectional view illustrating a crystal resonator package.

FIG. 10 is a circuit diagram of a temperature compensation oscillator that includes a crystal resonator.

FIG. 11 is a cross-sectional side view of the crystal resonator according to the embodiment of the present disclosure.

FIG. 12 is a circuit diagram of a temperature compensation oscillator that includes a crystal resonator.

FIG. 13 is a longitudinal cross-sectional view illustrating another example of a configuration of the crystal resonator.

FIG. 14 is a characteristic diagram illustrating characteristics of the crystal resonator according to the embodiment.

FIG. 15 is a characteristic diagram illustrating characteristics of the crystal resonator according to the embodiment.

FIG. 16 is a transparent perspective view illustrating a boundary surface of a crystal element where twins are formed.

FIG. 17 is a transparent perspective view illustrating a boundary surface of a crystal element where twins are formed.

FIG. 18 is a characteristic diagram illustrating characteristics of the crystal resonator according to the embodiment.

### DETAILED DESCRIPTION

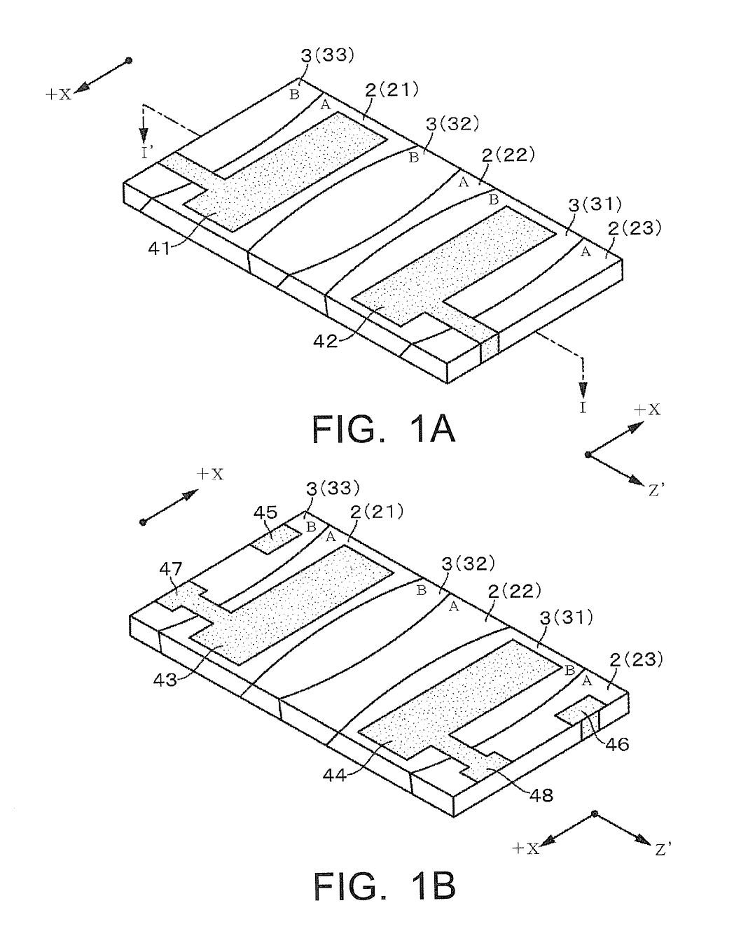

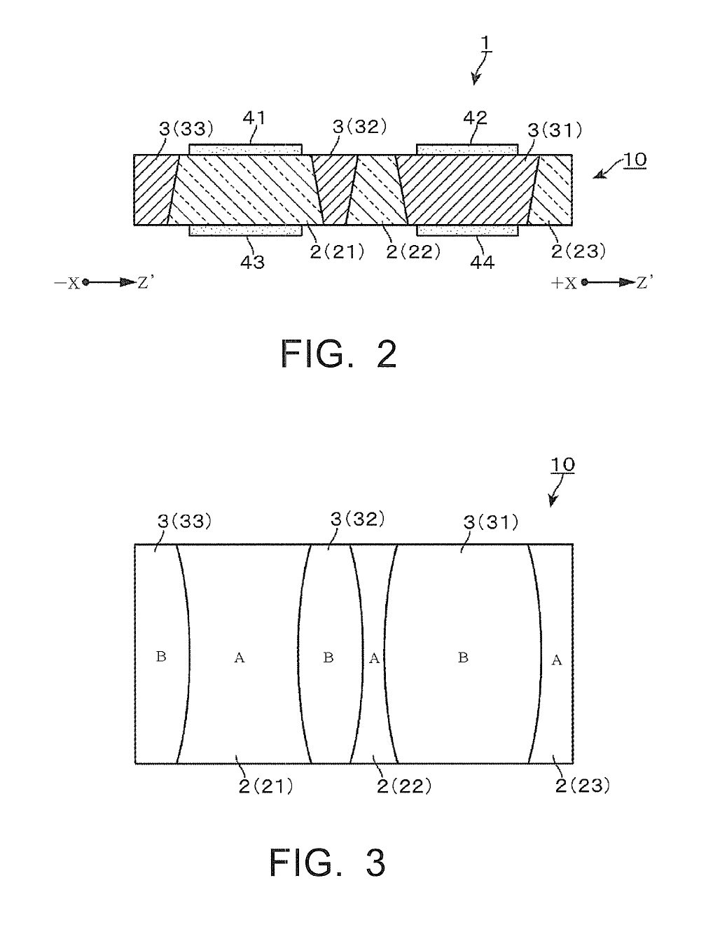

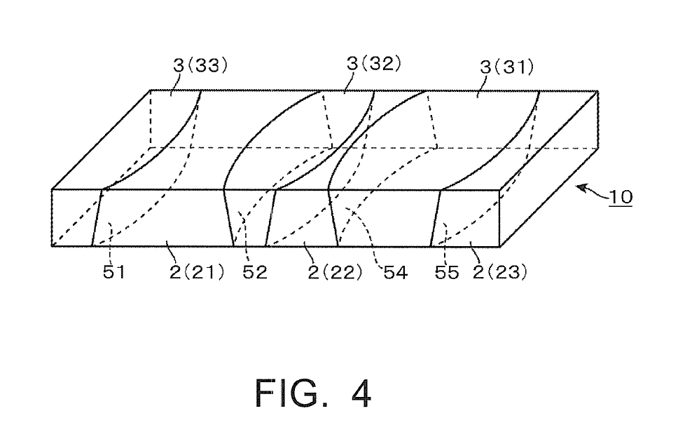

Regarding a crystal resonator 1 according to an embodiment of the present disclosure, FIG. 1A, FIG. 1B and FIG. 2 illustrate the crystal resonator according to the embodiment of the present disclosure. FIG. 3 and FIG. 4 illustrate a crystal element used in the crystal resonator. The crystal resonator 1 employs, for example, a crystal element 10 in a rectangular shape with a short side of 2.5 min and a long side of 5.0 mm. The crystal element 10 employs, for example, twins where an α crystal region 2 of an AT-cut crystal and a β crystal region 3 are formed. The β crystal region 3 has a crystal axis inverted with respect to that of the α crystal region. In the drawings, A denotes the α crystal region while B denotes the β crystal region.

Here, twins will be described. The α crystal region 2 is, for example, an AT-cut region, and includes a front surface and a back surface that are formed parallel to a surface formed by the Z′-axis and the X-axis. The Z′-axis is inclined counterclockwise at about 35° with respect to the Z-axis as a crystallographic axis extending in the length direction of the crystal element 10 when viewed from a positive direction of the X-axis extending in the width direction of the crystal element 10. On the other hand, the β crystal region 3 is constituted to have a front surface and a back surface that are formed parallel to a surface formed by the Z′-axis and the X-axis, and to have an opposite positive/negative direction along the X-axis with respect to the positive/negative direction of the α crystal region 2 along the X-axis. That is, this crystal element 10 is constituted as electrical twins. The β crystal region 3 is constituted approximately as a BT-cut region.

In the crystal resonator 1 according to the embodiment of the present disclosure, each three of the β crystal regions and the α crystal regions are alternately arranged from one end side toward the other end side in the length direction (the direction of Z′-axis) of the crystal element. As the α crystal regions, a first α crystal region 21, a second α crystal region 22, a third α crystal region 23 are arranged from the one end side toward the other end side. As the β crystal regions, a first β crystal region 31, a second β crystal region 32, a third β crystal region 33 are arranged from the other end side toward the one end side. The first α crystal region 21 and the first β crystal region 31 are each formed with a length of 2.3 mm. The second β crystal region 32, the third id crystal region 33, the second α crystal region 22, and the third α crystal region 23 are each formed with a length of 0.1 mm. The first α crystal region includes excitation electrodes 41 and 43 each in a rectangular shape with a size of 2.0 mm×2.0 mm and a thickness of 100 nm on a front surface side and a back surface side of the first α crystal region. The excitation electrodes 41 and 43 are each formed of, for example, a laminated body where an Au layer is laminated on a Cr layer. Thus, a first vibrating region is formed. On the front surface side and the back surface side of the first β crystal region 31, excitation electrodes 42 and 44 are disposed with similar shapes so as to form a second vibrating region.

The excitation electrode 41 on the top surface side includes an electrode end 45 formed in an end portion at the inferior surface side of the crystal element 10 via an extraction electrode drawn to a side surface at the one end side of the crystal element 10. An electrode end 47 is formed in the end portion on the inferior surface on the one end side of the crystal element 10 via an extraction electrode drawn from the excitation electrode 43 on the inferior surface side. The excitation electrode 42 includes an electrode end 46 formed in an end portion on the inferior surface side of the crystal element 10 via an extraction electrode drawn to a side surface on the other end side of the crystal element 10. The excitation electrode 44 includes an electrode end 48 formed via an extraction electrode drawn to the end portion on the inferior surface at the other end side.

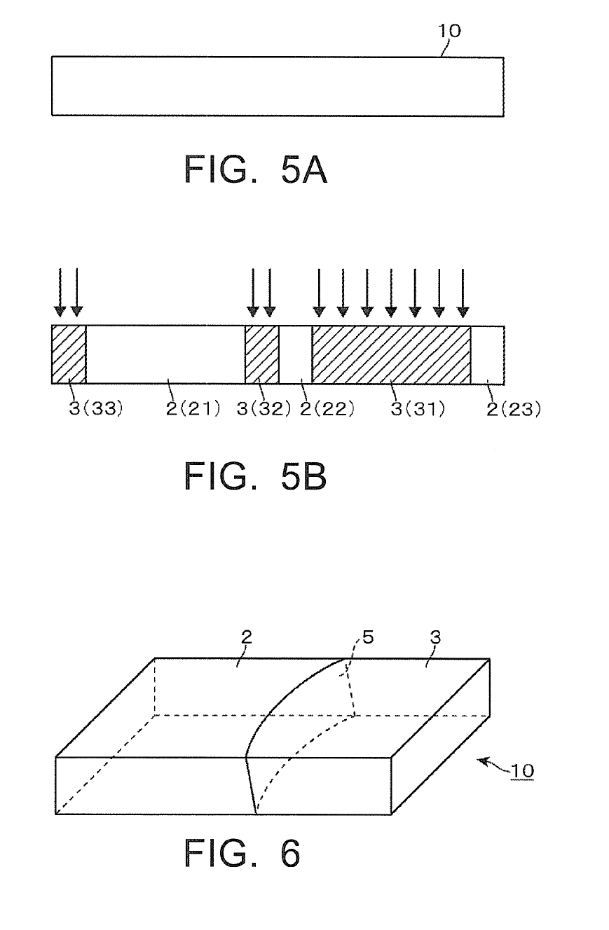

A method for fabricating the crystal resonator 1 will be described. For example, as illustrated in FIG. 5A, a product of the crystal element 10 in an AT-cut rectangular shape is used. As illustrated in FIG. 5B, a mask is put on a portion to be the a, crystal region 2 of this crystal element 10. Subsequently, laser irradiation is performed to heat the portion to, for example, 600° C. A crystal has a characteristic that causes phase transition at excess of 573° C. and inverts the crystallographic axis when cooled to equal to or less than 573° C. again. Thus, in the crystal element 10, a region on which the laser is irradiated causes the phase transition. In the example using the AT-cut crystal, this region becomes the region of the BT-cut crystal. Subsequently, as illustrated in FIG. 2, the excitation electrodes 41, 42, 43, and 44 and the extraction electrodes where the electrode ends 45, 46, 47, and 48 are formed are disposed on both surfaces of the respective first α crystal region 21 and first β crystal region 31. Thus, the crystal resonator 1 is obtained.

Here, a description will be given of the boundary surface between the α crystal region 2 and the β crystal region 3 when the twins are formed. In the case where a part of the crystal is heated at a temperature equal to or more than 573° C., the crystalline structure of the crystal undergoes a phase transition. The crystalline structure of the crystal changes. Subsequently, when the crystal is cooled, the phase transition occurs such that the crystal has a polarity in the opposite direction to that of the crystal before the phase transition so as to be a β crystal. These phase transitions are changes in units of crystal. Accordingly, the boundary surface between the region of the α crystal and the region of the β crystal is formed along the direction of the lattice of the crystal.

For example, the AT-cut crystal element 10 has a rectangular plate shape where a long side is along the Z′-axis direction and a short side is along the X-axis direction. The crystal element 10 is divided into two of right and left portions by the center line passing through the respective middle points on the long side facing one another. One region is heated to form a BT-cut crystal region. This case will be described as an example. As illustrated in FIG. 6, the boundary surface 5 is formed in the crystal element 10 between the AT-cut α crystal region 2 and the BT-cut β crystal region 3. The boundary surface 5 is inclined to the α crystal region 2 side with respect to the Y′-Z′ plane, and has a curved surface with a curve convex to the α crystal region 2 side with respect to the X-Z′ plane. On the other hand, the crystal element 10 is cut out in a rectangular flat plate shape. The side surface of the crystal element 10 is cut to be a planar surface. Accordingly, the α crystal region 2 does not have a symmetrical shape. Similarly, in the β crystal region, the boundary surface 5 and the surface facing the boundary surface 5 are not symmetrical to each other. Accordingly, the β crystal region 3 does not also have a symmetrical shape. In the case where the excitation electrodes 41 and 42 are disposed in a crystal region in an asymmetrical shape and oscillation is performed, symmetric vibration does not appear. Therefore, the vibration is not stable and Activity dips are likely to appear in oscillation frequency.

In the crystal resonator 1 according to the embodiment of the present disclosure, as illustrated in FIG. 3, the third β crystal region 33, the first α crystal region 21, the second β crystal region 32, the second α crystal region 22, the first β crystal region 31, and the third α crystal region 23 are formed in this order along the length direction of the crystal element 10. The respective excitation electrodes 41 and 42 are disposed in the first α crystal region 21 and the first β crystal region 31 to form the respective first vibrating region and second vibrating region.

As described above, assuming that a part of the AT-cut crystal is an axis-inverted region, the boundary surface 5 between the α crystal region 2 and the β crystal region 3 becomes a curved surface that penetrates into the α crystal region 2 side. Therefore, a boundary surface 51 between the third β crystal region 33 and the first α crystal region 21 becomes a curved surface depressed toward the first α crystal region side. On the other hand, a boundary surface 52 between the first α crystal region 21 and the second β crystal region 32 becomes a curved surface depressed toward the first α crystal region 21 side. That is, the first α crystal region 21 has a shape where the boundary surfaces 51 and 52 are both depressed toward the first α crystal region 21 side. The first β crystal region 31 is a region sandwiched between the second α crystal region 22 and the third α crystal region 23. Therefore, a boundary surface 54 between the first β crystal region 31 and the second α crystal region 22 and a boundary surface 55 between the first β crystal region 31 and the third α crystal region 23 have curved surfaces curved toward the respective second α crystal region 22 and a third α crystal region 23.

Accordingly, the first α crystal region 21 has a symmetrical shape. Vibration is not generated in the second α crystal region 22, the third α crystal region 23, the second β crystal region 32 and the third β crystal region 33 where the excitation electrodes 41, 42, 43, and 44 are not disposed. Accordingly, the first α crystal region 21 forms a fixed end of the vibration in a position at the boundary surface between the second β crystal region 32 and the third β crystal region 33. If the boundary surface is a free end, a distribution pattern of the vibration energy is disturbed due to the influence of a reflected wave reflected from the boundary surface. However, designing the boundary surface as a fixed end can reduce this disturbance. Accordingly, the distribution pattern of the vibration energy in the crystal resonator 1 has a high symmetry. Thus, in the case where the excitation electrode 41 is disposed in the first α crystal region 21 and oscillation is performed, Activity dips are unlikely to occur. Similarly in the first β crystal region 31, the second vibrating region forms a fixed end of the vibration in a position at the boundary surface between the second α crystal region 22 and the third α crystal region 23. This increases the symmetry of the distribution pattern of the vibration energy, thus stabilizing the oscillation frequency.

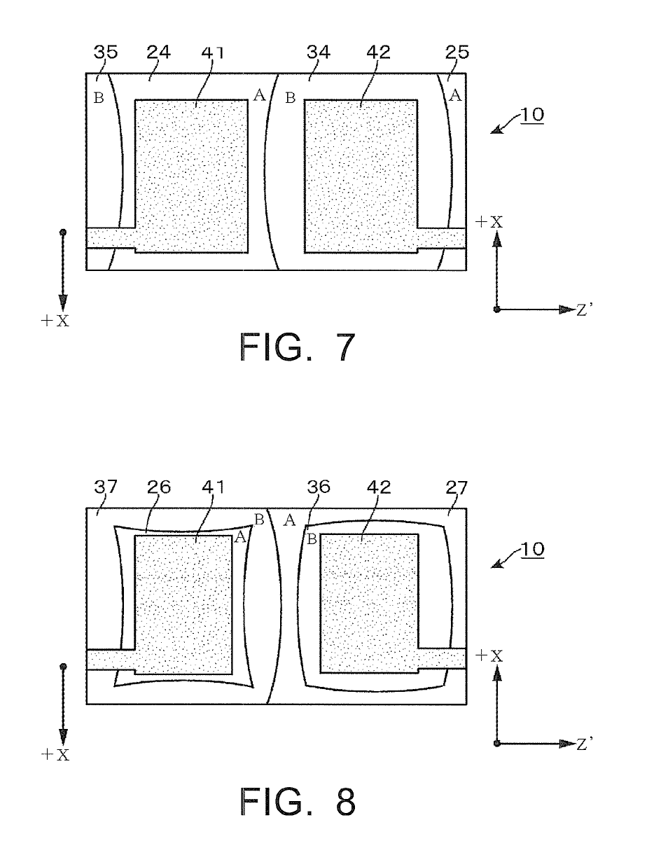

The crystal resonator 1 according to another embodiment does not need to have a row of the α crystal regions 2 and the β crystal regions 3 between the first α crystal region 21 and the first β crystal region 31. As illustrated in FIG. 7, each two or more of the α crystal regions and the β crystal regions may be alternately arranged in the configuration. For example, an α crystal region 24 to be the first vibrating region is sandwiched between a β crystal region 34 and a β crystal region 35 to be the second vibrating regions, thus having a symmetrical shape. This increases the symmetry of the vibration. Similarly, the β crystal region 34 is sandwiched between the α crystal region 24 and the α crystal region 25, thus having a symmetrical shape. This increases the symmetry of the vibration.

However, in the case where the β crystal region 34 is oscillated, the boundary surface between the α crystal region 24 and the β crystal region 34 behaves as a boundary surface with the β crystal region that vibrates. On the other hand, the boundary surface between the α crystal region 24 and the β crystal region 35 behaves as a boundary surface with the β crystal region that does not vibrate. The boundary surface with the β crystal region that vibrates repeats deformation, and has different conditions from those of the boundary surface with the β crystal region that does not vibrate. Accordingly, the symmetry of the α crystal region 24 collapses slightly. A similar thing holds true for the β crystal region 34. Also in the case where the first α crystal region 21 and the first β crystal region 31 vibrate without disposing a row of the a crystal regions 2 and the β crystal regions 3 between the first α crystal region 21 and the first β crystal region 31, the symmetry is maintained. Thus, Activity dips are unlikely to occur.

With the above-described embodiment, in the crystal element, the respective excitation electrodes 41 and 42 are formed on both surfaces of the first α crystal region 21 and the first β crystal region 31 that have mutually different positive/negative directions along the X-axis. Thus, the vibrating regions are formed. Further, the second β crystal region is disposed to form the boundary surface facing the boundary surface with the β crystal region of the first α crystal region across the first α crystal region. The second α crystal region is disposed to form the boundary surface facing the boundary surface with the α crystal region of the first β crystal region across the first β crystal region. Accordingly, the first α crystal region 21 is sandwiched between the β crystal regions 31 and 32 from both sides. The third β crystal region 33 is also sandwiched between the α crystal regions 22 and 23 from both sides. Therefore, the first α crystal region 21 and the third β crystal region 33 both have a symmetrical shape. Accordingly, when the respective regions are oscillated, the symmetry of the vibration becomes high. This reduces the occurrence of Activity dips.

Here, when the crystal resonator is designed, reduction of unwanted response becomes a challenge. The oscillation frequency of the unwanted response is determined by dimensions and temperature of the crystal element. Accordingly, the crystal element needs to be designed to reduce the unwanted response such that a simulation is performed to predict the oscillation frequency of the unwanted response in advance. The oscillation frequency of the unwanted response of the crystal resonator is obtained by analysis using a finite element method. Firstly, the surface of the crystal element is partitioned into a mesh, and divided regions are set on the surface of the crystal element. Subsequently, the dimensions, the material constants, the boundary conditions, and similar parameter of the crystal element are used to determine a model to be used for frequency analysis. This model is used to create a matrix that indicates a displacement amount and an electric charge amount in each mesh. The obtained matrix is plotted as a mesh and a natural frequency analysis or a frequency response analysis is performed, so as to obtain a frequency of high frequency components containing unwanted response oscillated by the crystal element. The obtained frequency is used to create a mode chart showing, for example, dimensions and a frequency of the crystal element, so as to determine design dimensions for reducing the unwanted response.

In the case where twins are formed in a common crystal element, the α crystal region and the β crystal region vibrate independently from each other. Therefore, it is necessary to design dimensions that reduce the unwanted response by predicting unwanted response for each region. Accordingly, it is necessary to obtain respective dimensions of the crystal regions so as to evaluate unwanted response for each crystal region. However, as described above, the boundary surface between the α crystal region and the β crystal region in the twins is formed along the crystalline structure of the crystal, thus being formed to be inclined. Specifically, for example, in the case where the AT-cut α crystal region and the BT-cut β crystal region are formed to be arranged along the Z′-axis direction, the boundary surface between the α crystal region and the β crystal region is formed to be inclined at 25° to 45° when viewed from the X-axis direction.

Accordingly, in case of the crystal element where twins are formed, firstly, a horizontal distance of a position difference of the boundary surface formed in the crystal element in the Z′-axis direction is measured between a front surface side and a back surface side of crystal element, so as to determine, for example, an angle θ of the boundary surface viewed from the X-axis direction. Subsequently, the dimensions and the boundary conditions of the crystal element when the unwanted response is predicted in each crystal region are corrected reflecting the angle θ at which the boundary surface is formed, so as to correctly predict the unwanted response. Here, for the analysis, a commercially available FEM analysis software was used. In the analysis, a model was created using the rectangular crystal and a plurality of pairs of the gold electrode, and dimensions, material constants, boundary conditions, and similar parameter of the model were input. With the analysis solution, displacement and a potential for each element are obtained. Subsequently, the natural frequency analysis or the frequency response analysis is calculated to understand behaviors of the main vibration and the unwanted response.

Also in the case where the excitation electrodes 41 to 44 are mounted on the first α crystal region 21 and the first β crystal region 31, it is necessary not to include the boundary surface in the vibrating region by taking into consideration the inclination of the boundary surface. In case of the twins, a crystalline structure of the formed crystal region determines the inclination of the boundary surface. Accordingly, the positions to dispose the excitation electrode are preliminarily designed to avoid a region including the boundary surface.

As illustrated in FIG. 8, another example may be constituted such that the peripheral area of the α crystal region 26 to be a first vibrating region is surrounded by a β crystal region 37 while the peripheral area of a β crystal region 36 to be a second vibrating region is surrounded by the α crystal region 27. The boundary surfaces in four directions of the α crystal region 26 become boundary surfaces between the α crystal and the β crystal. The respective facing boundary surfaces have mutually symmetrical shapes. Accordingly, the α crystal region 26 has a symmetrical shape. Symmetric vibrations are generated by oscillation of the α crystal region 26. Similarly, the boundary surfaces in four directions of the β crystal region 36 become boundary surfaces between the α crystal and the β crystal. The respective facing boundary surfaces have mutually symmetrical shapes. Accordingly, the β crystal region 36 has a symmetrical shape. Symmetric vibrations are generated by oscillation of the β crystal region 36. Thus, similar effects are obtained.

### Application Example

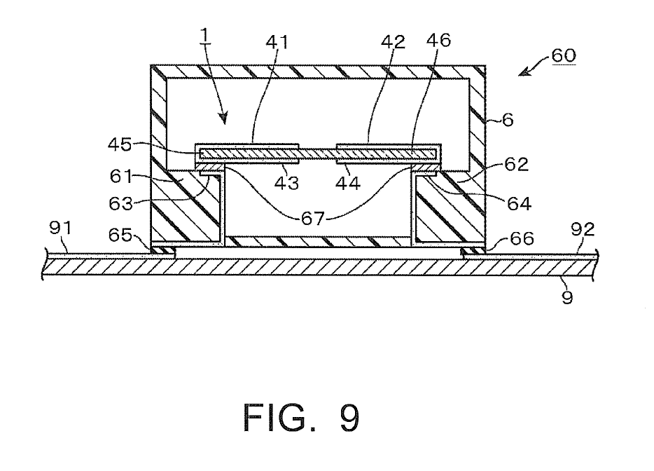

An application example using the crystal resonator 1 of the present disclosure includes a crystal oscillator. For example, as illustrated in FIG. 9, the crystal resonator 1 is housed in a container 6 made of, for example, alumina or glass, so as to constitute a crystal resonator package 60. Within the container 6, pedestal portions 61 and 62 are formed to form a supporting portion that supports the crystal resonator 1 at both ends. The pedestal portions 61 and 62 have the top surfaces where respective connection electrodes 63 and 64 are formed. The connection electrodes 63 and 64 are connected to pads 65 and 66 via the respective inner bottom surfaces of the pedestal portions 61 and 62 and a through-hole passing through the bottom wall of the container 6. The pads 65 and 66 behave as electrode portions electrically connected to external conductive paths disposed on the outer bottom surface of container 6.

The crystal resonator 1 is secured with a conductive adhesive 67 so as to electrically connect the electrode end 45 and the connection electrode 63 together. Similarly, the conductive adhesive 67 electrically connect the electrode end 46 and the connection electrode 64 together. Accordingly, the crystal resonator 1 is secured onto the pedestal portions 61 and 62. Although not illustrated in the drawing, the electrode ends 47 and 48 are also electrically conducted with connection electrodes that are disposed on the pedestal portions 61 and 62. The electrode ends 47 and 48 are drawn to the outer bottom surface of the container 6, so as to form pads. This crystal resonator package 60 is electrically connected by, for example, conductive paths 91 and 92 and pads on a printed circuit board 9.

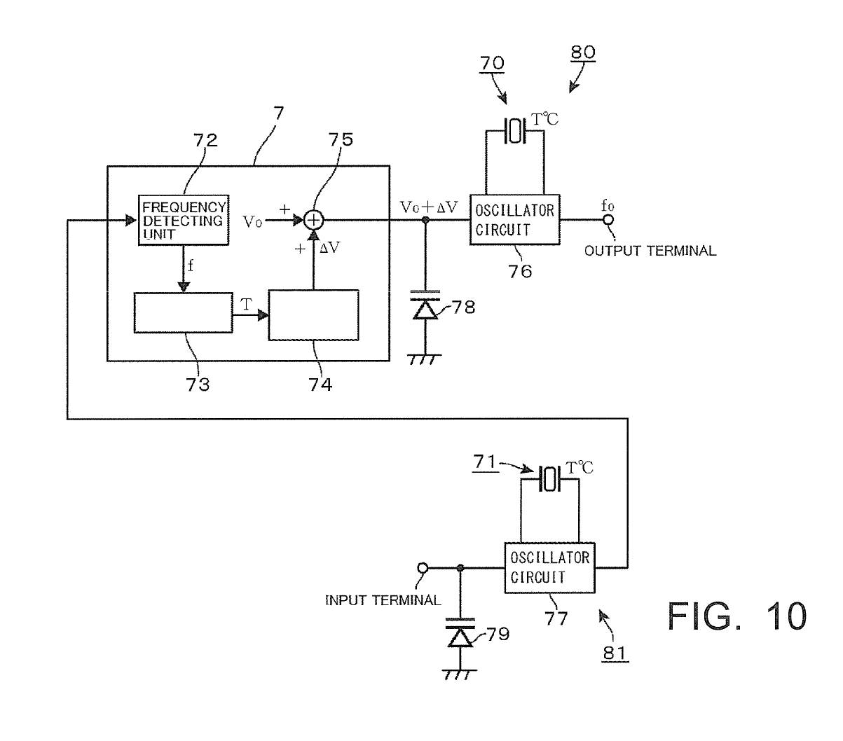

The above-described crystal resonator package 60 is mounted on the printed circuit board 9 together with the oscillator circuit and peripheral elements so as to constitute an oscillation device. FIG. 10 illustrates an exemplary oscillation device. This oscillation device is a temperature compensated crystal oscillator (TCXO) constituted using the above-described crystal resonator 1. The crystal resonator of the present disclosure includes two vibrating regions that vibrate independently from each other. In the following description, for convenience, this crystal resonator is illustrated as two crystal resonators. In the crystal resonator 1, the first α crystal region 21 where the excitation electrodes 41 and 43 are disposed is assumed to be a first crystal resonator 70. The third β crystal region 33 where the excitation electrodes 42 and 44 are disposed is assumed to be a second crystal resonator 71.

In this TCXO, firstly, an auxiliary oscillating unit 81 is oscillated to output a high frequency. The auxiliary oscillating unit 81 is constituted of an oscillator circuit 77 connected to the second crystal resonator 71. A frequency “f” of this high frequency is detected by a frequency detecting unit 72 and is input to a temperature estimation unit 73. The temperature estimation unit 73 calculates an ambient temperature T of the crystal resonator 1 using frequency information. The compensation voltage operator 74 uses the calculated temperature T to calculate a compensation voltage ΔV for compensating an error of the frequency due to the temperature difference in oscillation frequency of the first crystal resonator 70. The voltage compensation unit 75 adds the compensation voltage ΔV to a voltage V₀ to be input to the oscillator circuit 76, so as to compensate the error of the oscillation frequency due to the temperature in the first crystal resonator 70. This stabilizes an oscillation frequency f₀ of a main oscillating unit 80. In the drawing, reference numerals 78 and 79 denote varicap diodes.

In the BT-cut crystal, the temperature and the frequency change rate have an almost proportional relationship in a temperature zone of, for example, a room temperature from 0° C. to 30° C. Therefore, a clear frequency change can be taken out. Accordingly, the second crystal resonator 71 is used as a crystal resonator for temperature compensation to allow an oscillator to oscillate a stable frequency with simple configuration.

The frequency detecting unit 72, the temperature estimation unit 73, the compensation voltage operator 74, and the voltage compensation unit 75 are disposed inside of an integrated circuit chip 7.

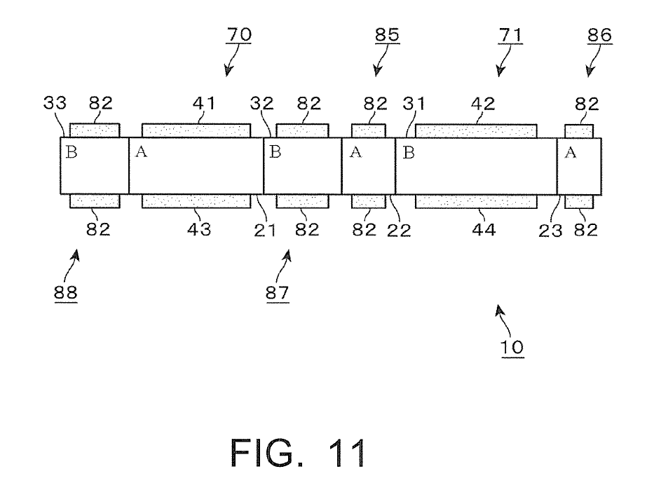

Other than the first α crystal region 21 to be the first crystal resonator 70 and the first β crystal region 31 to be the second crystal resonator 71, the second α crystal region 22, the third a crystal region 23, the second β crystal region 32, and the third β crystal region 33 may be used as crystal filters or capacitors. For example, as illustrated in FIG. 11, respective electrodes 82 for excitation are disposed on both surfaces of the second α crystal region 22 and the third α crystal region 23 so as to constitute a first waveform shaping crystal resonator 85 and a second waveform shaping crystal resonator 86. Additionally, respective electrodes 82 for excitation are disposed on both surfaces of the second β crystal region 32 and the third β crystal region 33 so as to constitute a first capacitor-use crystal resonator 87 and a second capacitor-use crystal resonator 88.

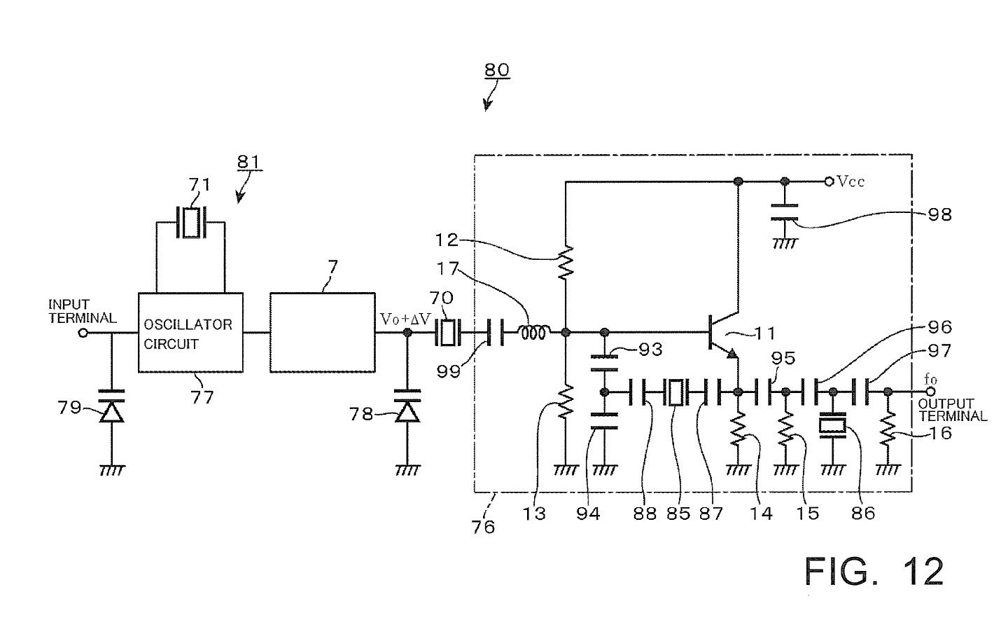

The above-described crystal resonator is incorporated in the TCXO as illustrated in a circuit diagram of FIG. 12. The oscillator circuit 76 disposed in the main oscillating unit for taking out the oscillation frequency can employ, for example, a Colpitts circuit. In the drawing, reference numeral 11 denotes a transistor that constitutes an amplifier. Reference numerals 12 and 13 denote resistors. Reference numerals 93, 94, 98, and 99 denote capacitors. Reference numeral 17 denotes an extension coil. In this oscillator circuit, the first crystal resonator 70, the capacitor 99, and the extension coil 17 constitute the oscillating unit.

Between the middle point of the capacitors 93 and 94 and an emitter of the transistor 11, the second capacitor-use crystal resonator 88, the first waveform shaping crystal resonator 85, and the first capacitor-use crystal resonator 87 are connected in series in this order from the side of the capacitors 93 and 94. The second capacitor-use crystal resonator 88 and the first capacitor-use crystal resonator 87 behave capacitors for adjusting impedance, and have the function of adjusting capacitance so as to obtain resonance within the oscillation loop.

In the oscillator circuit, a circuit is disposed for taking out an output frequency signal at the emitter side of the transistor 11 and outside of the oscillation loop. This circuit includes the capacitors 95, 96, and 97. The second waveform shaping crystal resonator 86 is connected in parallel between the capacitor 96 and 97. In the drawing, reference numerals 14, 15, and 16 denote resistors. In the case where excitation electrodes are disposed in the common crystal element so as to form the first vibrating region and the second vibrating region, floating capacitance is generated between the excitation electrode disposed in the first vibrating region and the excitation electrode disposed in the second vibrating region. Accordingly, when the first and second vibrating regions are oscillated, distortion of a sine wave occurs due to the influence of the floating capacitance.

In the above-described TCXO, the first α crystal region 21 to be the first crystal resonator for taking out a frequency for oscillation is constituted to be sandwiched between the second β crystal region 32 and the third β crystal region 33. Therefore, the first α crystal region 21 has high symmetry of the shape. This reduces the distortion of the sine wave due to influence of the reflected wave reflected at the boundary surface. Inside of the oscillation loop, the first waveform shaping crystal resonator 85 is connected. Outside of the oscillation loop, the second waveform shaping crystal resonator 86 is connected. Accordingly, when the first crystal resonator 70 for frequency oscillation is oscillated, a sine wave oscillated from the first crystal resonator 70 is shaped by passing through the first waveform shaping crystal resonator 85. Further, a frequency signal passes through the second waveform shaping crystal resonator 86 at the output side of the oscillator outside of the oscillation loop, so as to further shape the frequency signal. This removes noise components of the frequency signal oscillated from the above-described TCXO, thus reducing the phase noise.

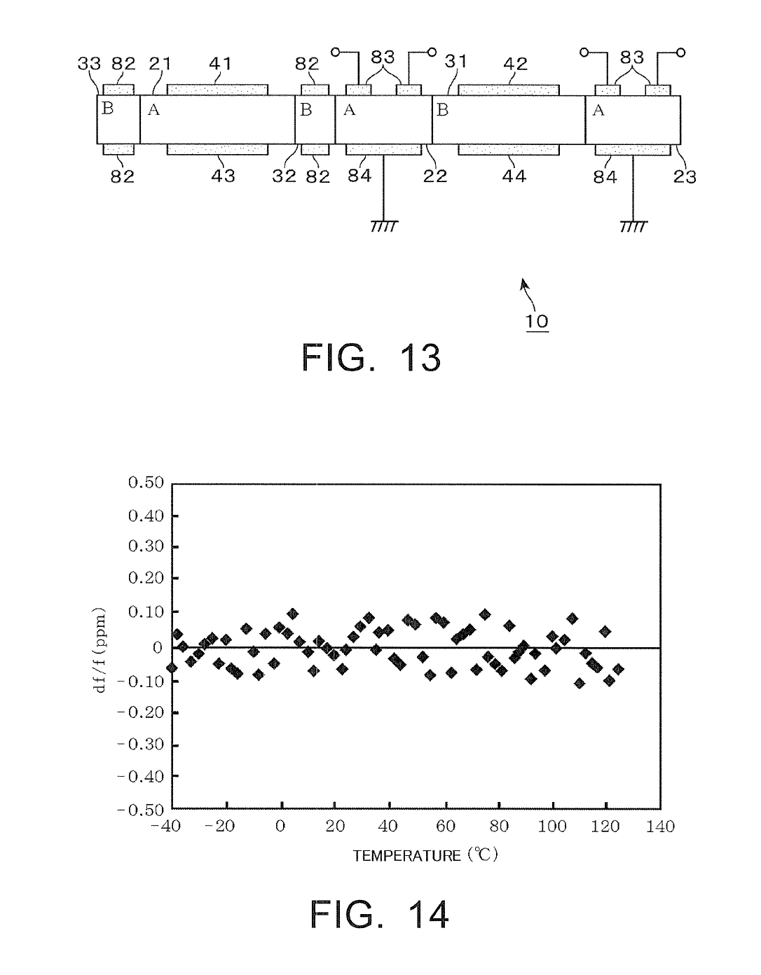

The first and second waveform shaping crystal resonators 85 and 86 to be used as crystal filters may be monolithic crystal filters (MCF). For example, as illustrated in FIG. 13, two excitation electrodes 83 are disposed on the front surface side of the second α crystal region 22 and the third α crystal region 23, and excitation electrodes 84 are disposed across the two excitation electrodes 83 at the back surface side. The excitation electrodes 83 are each connected to the circuit. The excitation electrodes 84 are set at the ground potential. In case of this configuration, similar effects can be obtained.

Further, the oscillator circuit is not limited to the Colpitts circuit, and may employ a Pierce-type oscillator circuit or a Butler-type oscillator circuit. In each oscillator circuit, another α crystal region is connected inside of the oscillation loop or at the output terminal side outside of the oscillation loop, so as to obtain similar effects. The present disclosure may be applied to an OCXO. Also in case of configuration where a waveform shaping crystal resonator is connected to one of the inside and the outside of the oscillation loop, advantageous effects are provided.

(Verification Test 1)

To validate the advantageous effects of the crystal resonator 1 according to the embodiment of the present disclosure, the following test was carried out. A working example employs the crystal resonator 1 with a configuration similar to that of the crystal resonator illustrated in FIG. 1A and FIG. 1B.

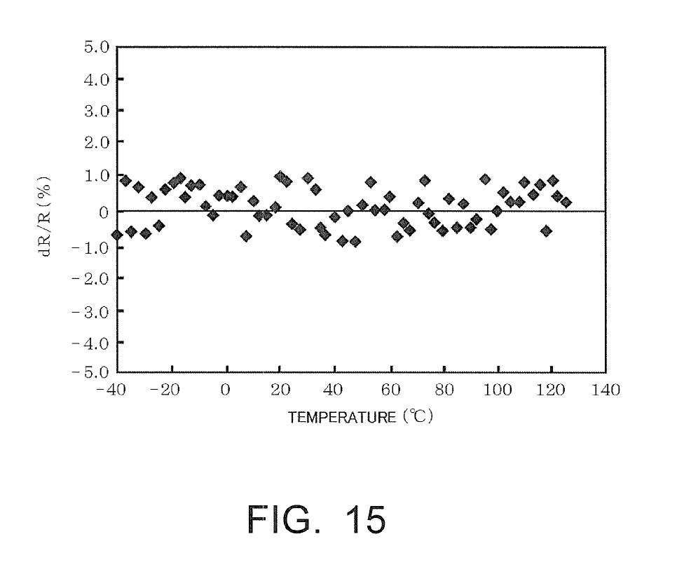

Regarding the crystal resonator 1 of the working example, temperature characteristics of a resonance frequency and temperature characteristics of a motional resistance were examined applying a n circuit technique. Here, the drive current of the crystal resonator 1 is 2 mA±10%. The resonance frequency was detected from −40° C. to 125° C. at intervals of 2.5° C. to obtain a fourth-order regression formula approximated by a detected value. The motional resistance was detected at a similar temperature. FIG. 14 is a characteristic diagram illustrating a relationship between a respective resonance frequencies and temperatures in the working example. In each temperature calculated from the approximation formula, a value obtained by dividing the difference between a calculation value and a measured value of the resonance frequency by the measured value is expressed in ppm. This value is plotted for each temperature. FIG. 15 is a characteristic diagram illustrating a relationship between a motional resistance and a temperature in the working example. A value obtained by dividing the difference between an average value and a measured value of the detected value by the measured value is expressed in ppm. This value is plotted for each temperature.

With this result, the difference between the calculation value and the measured value of the resonance frequency is within a range equal to or less than 0.1 ppm. Accordingly, Activity dips and frequency jump did not occur. The difference between the average value and the measured value of the detected value of the motional resistance is also within a range equal to or less than 1 ppm. Accordingly, an increase in motional resistance was not observed. It is found that Activity dips can be reduced in the case where the crystal resonator 1 of the working example of the present disclosure is used.

(Verification Test 2)

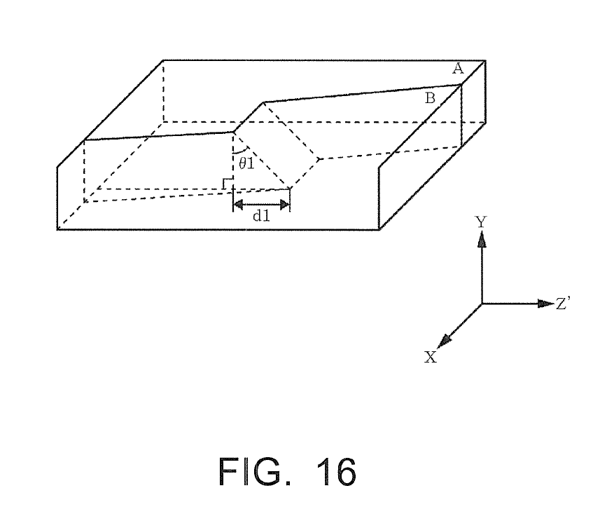

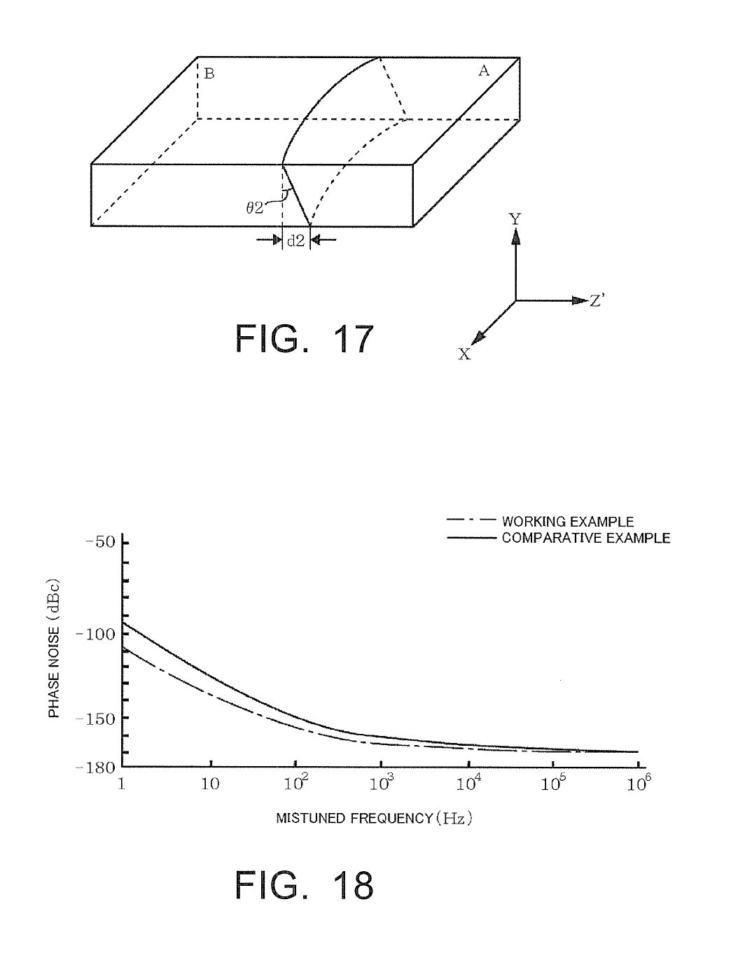

The following test was carried out to measure an angle at which the boundary surface is formed when twins are formed in the crystal element. A pressure at 2.3 GPa and a heat at 550° C. were applied to an AT-cut crystal element with a diameter of 3 inches and a thickness of 0.25 mm so as to form an axis-inverted portion (the β crystal region). At this time, a distance in the horizontal direction was measured between: a position of the boundary line between the a crystal region and the β crystal region on the front surface side of the crystal element, and a position of the boundary line between the α crystal region and the β crystal region on the back surface side of the crystal element. FIG. 16 illustrates a state of the boundary surface when the a crystal region and the β crystal region are formed to be arranged along the X-axis direction. FIG. 17 illustrates a state of the boundary surface when the α crystal region and the β crystal region are formed to be arranged along the Z′-axis direction.

As illustrated in FIG. 16, when the α crystal region and the β crystal region are formed to be arranged along the X-axis direction, a distance d1 was 0.25 mm. The distance d1 is a distance of a position difference in the Z′-axis direction between the boundary surface on the front surface side of the crystal element and the boundary surface on the back surface side of the crystal element. On the other hand, in the X-axis direction, these boundary surfaces were formed approximately at the same position. Therefore, an inclination θ1 of the boundary surface becomes 45° viewed from the X-axis direction.

As illustrated in FIG. 17, when the α crystal region and the β crystal region are formed to be arranged along the Z′-axis direction, a distance d2 was 0.12 mm. The distance d2 is a distance of a position difference in the Z′-axis direction between the boundary surface on the front surface side of the crystal element and the boundary surface on the back surface side of the crystal element. On the other hand, in X-axis direction, these boundary surfaces were formed approximately at the same position. Therefore, an inclination θ2 of the boundary surface becomes 25.64° viewed from the X-axis direction.

(Verification Test 3)

The following test was carried out to validate the advantageous effects of the crystal resonator 1 according to the embodiment of the present disclosure. A crystal oscillator according to the working example employed the crystal resonator illustrated in FIG. 12. A crystal resonator for oscillation employed the first α crystal region 21. In the oscillator circuit, the second capacitor-use crystal resonator 88 constituted of the third β crystal region 33 and the first waveform shaping crystal resonator 85 constituted of the second α crystal region 22 are connected in series between the emitter and the middle point of the capacitors 93 and 94. At the output terminal side of the emitter, the first capacitor-use crystal resonator 87 constituted of the second β crystal region 32 and the second waveform shaping crystal resonator 86 constituted of the third α crystal region 23 are connected in series. This oscillator circuit is otherwise similar to the oscillator circuit 76 in FIG. 12. A comparative example has a configuration where the second capacitor-use crystal resonator 88, the first waveform shaping crystal resonator 85, the first capacitor-use crystal resonator 87 and the second waveform shaping crystal resonator 86 are not connected to the oscillator circuit.

The crystal resonators according to the working example and the comparative example are used to constitute oscillator circuits. Each output terminal is connected to a buffer amplifier. The mistimed frequency and the noise level for each output were examined.

FIG. 18 illustrates a result of the examination, and a characteristic diagram illustrating a mistuned frequency on horizontal axis and a noise level on the longitudinal axis. In the case where the crystal resonator according to the working example is used, the phase noise is found to be reduced.

What is claimed is:

1. A crystal resonator, comprising:
a crystal element that includes an α crystal region and a β crystal region, the α crystal region and the β crystal region having mutually different positive/negative directions along an X-axis, each two or more of the α crystal regions and the β crystal regions being alternately formed along a direction perpendicular to the X-axis; and
excitation electrodes formed on both surfaces of the respective α crystal region and β crystal region other than crystal regions positioned at both end portions of a row of the α crystal regions and the β crystal regions.

2. The crystal resonator according to claim 1, wherein
the crystal element has a rectangular shape.

3. The crystal resonator according to claim 1, wherein
the crystal element is formed in a rectangular shape, the rectangular shape having a long side that extends in an extending direction of the X-axis.

4. The crystal resonator according to claim 1, wherein
a row of the α crystal regions and the β crystal regions intervenes between the α crystal region where the excitation electrode is disposed and the β crystal region where the excitation electrode is disposed.

5. The crystal resonator according to claim 1, wherein
a boundary surface between the α crystal region and the β crystal region is a surface inclined at 25° to 45° with respect to a longitudinal direction when viewed from a direction of the X-axis.

6. The crystal resonator according to claim 1, wherein
the crystal element is cut out by AT cut, and
one region of the α crystal region and the β crystal region is an AT-cut region that has a positive/negative direction along the X-axis, the positive/negative direction being a same as a positive/negative direction when the crystal element is cut out.

7. A crystal resonator package, comprising:
the crystal resonator according to claim 6 within a container; and
an electrode portion disposed at the container, the electrode portion electrically connecting respective excitation electrodes and an external conductive path.

8. A crystal oscillator, comprising:
the crystal resonator according to claim 6;
a first oscillator circuit connected to an excitation electrode disposed in the AT-cut region;
a second oscillator circuit connected to an excitation electrode disposed in a crystal region that has an opposite positive/negative direction along the X-axis with respect to the positive/negative direction of the AT-cut region; and
a correction unit configured to: estimate a temperature of the crystal resonator based on an output frequency of the second oscillator circuit; and correct a setting signal corresponding to a setting value of an oscillation frequency of the first oscillator circuit based on the estimated temperature.

9. The crystal oscillator according to claim 8, wherein
the AT-cut region includes a first AT-cut region and a second AT-cut region, the excitation electrode connected to the first oscillator circuit being disposed in the first AT-cut region, one of an inside and an outside of an oscillation loop of the first oscillator circuit being connected to a first waveform shaping crystal resonator, the first waveform shaping crystal resonator being configured to shape a frequency signal to a sine wave, and
the first waveform shaping crystal resonator is constituted such that an electrode for excitation is disposed in the second AT-cut region.

10. The crystal oscillator according to claim 8, wherein
the crystal region that has the opposite positive/negative direction along the X-axis with respect to the positive/negative direction of the AT-cut region includes: a crystal region that has an opposite positive/negative direction along the X-axis with respect to the positive/negative direction of the first AT-cut region along the X-axis; and a crystal region that has an opposite positive/negative direction along the X-axis with respect to the positive/negative direction of the second AT-cut region along the X-axis,
the excitation electrode connected to the second oscillator circuit is disposed in the crystal region that has the opposite positive/negative direction along the X-axis with respect to the positive/negative direction of the first AT-cut region along the X-axis,
the first waveform shaping crystal resonator is connected to a capacitor for adjusting impedance in series, and
the capacitor for adjusting impedance is constituted such that an electrode for excitation is disposed in the crystal region that has the opposite positive/negative direction along the X-axis with respect to the positive/negative direction of the second AT-cut region along the X-axis.

11. The crystal oscillator according to claim 9, further comprising:
a third AT-cut region as the AT-cut region, wherein
the inside and another side of the outside of the oscillation loop is connected to a second waveform shaping crystal resonator, the second waveform shaping crystal resonator being configured to shape a frequency signal to a sine wave, and
the second waveform shaping crystal resonator is constituted such that an electrode for excitation is disposed in the third AT-cut region.
